(19) United States
(12) Patent Application Publication
(10) Pub. No.: US 2015/0270242 A1
(43) Pub. Date: Sep. 24, 2015

(54) SEMICONDUCTOR PACKAGES AND METHODS OF FABRICATING THE SAME

(71) Applicants: Sang-Uk KIM, Cheonan-si (KR); SANGWON KIM, Asan-si (KR); TAESUNG PARK, Cheonan-si (KR); EUNCHUL AHN, Yongin-si (KR); CHOONGBIN YIM, Cheonan-si (KR); Seunghun HAN, Asan-si (KR)

(72) Inventors: Sang-Uk KIM, Cheonan-si (KR); SANGWON KIM, Asan-si (KR); TAESUNG PARK, Cheonan-si (KR); EUNCHUL AHN, Yongin-si (KR); CHOONGBIN YIM, Cheonan-si (KR); Seunghun HAN, Asan-si (KR)

(21) Appl. No.: 14/729,047

(22) Filed: Jun. 2, 2015

Related U.S. Application Data
(62) Division of application No. 14/064,106, filed on Oct. 25, 2013.

(30) Foreign Application Priority Data
Nov. 30, 2012 (KR) 10-2012-0138077

(51) Int. Cl. H01L 23/00; H01L 21/56; H01L 23/31

(52) U.S. Cl. CPC H01L 24/81; H01L 23/3114; H01L 24/03; H01L 24/06; H01L 21/563; H01L 2224/81815; H01L 2224/13024

(57) ABSTRACT

A semiconductor package includes a wiring board, a semiconductor chip mounted on the wiring board, and a mounting connection terminal electrically connecting a bonding pad of the semiconductor chip to a first connection pad of the wiring board. The mounting connection terminal includes a core portion and a connecting shell solder portion substantially surrounding the core portion. The core portion of the mounting connection terminal is not in contact with the bonding pad of the semiconductor chip.

### CROSS-REFERENCE TO RELATED APPLICATIONS

This U.S. non-provisional patent application is a divisional of U.S. patent application Ser. No. 14/064,106, filed Oct. 25, 2013 which claims priority under 35 U.S.C. §119 to Korean Patent Application No. 10-2012-0138077, filed on Nov. 30, 2012, the entirety of which is incorporated by reference herein.

### BACKGROUND

Embodiments relate to semiconductor packages and methods of fabricating the same and, more particularly, to semiconductor packages including semiconductor chips mounted by a flip chip bonding technique and methods of fabricating the same.

Electronic devices having lower weights, smaller sizes, higher speeds, multiple functions, higher performance, higher reliability and lower fabricating cost characteristics have been increasingly demanded with the development of an electronic industry. A packaging technique may be capable of satisfying such demands. A chip scale package (CSP) technique may provide a smaller semiconductor package of a semiconductor chip size level.

Additionally, higher capacity of the semiconductor packages may also be demanded along with the smaller size of the semiconductor packages. Fabrication techniques capable of increasing cells in a limited area may be used to improve the capacity of the semiconductor chips. The fabrication techniques may need high level techniques capable of realizing very fine patterns and having long developing times. Recently, to realize the higher capacity and smaller size semiconductor packages, research is being conducted for a multi-chip package including three-dimensionally stacked semiconductor chips and/or a stack type semiconductor package including three-dimensionally stacked semiconductor packages.

### SUMMARY

An embodiment includes a semiconductor package comprising: a wiring board having a first surface and a second surface opposite to the first surface; a semiconductor chip mounted on the first surface of the wiring board; and a mounting connection terminal electrically connecting a bonding pad of the semiconductor chip to a first connection pad of the wiring board, the mounting connection terminal including a core portion and a connecting shell solder portion substantially surrounding the core portion. The core portion of the mounting connection terminal is not in contact with the bonding pad of the semiconductor chip.

An embodiment includes a method of fabricating a semiconductor package, the method comprising: preparing a wiring board including a first connection pad; forming a wiring board-connection terminal on the first connection pad of the wiring board, the wiring board-connection terminal including a core portion and a connecting shell solder portion substantially surrounding the core portion; preparing a semiconductor chip including a bonding pad; forming a semiconductor chip-connection terminal on the bonding pad of the semiconductor chip; contacting the semiconductor chip-connection terminal to the wiring board-connection terminal; and performing a reflow process on the wiring board-connection terminal and the semiconductor chip-connection terminal to form a mounting connection terminal The mounting connection terminal includes the core portion and a mounting shell solder portion substantially surrounding the core portion; and the core portion of the mounting connection terminal is not in contact with the bonding pad of the semiconductor chip.

An embodiment includes a system comprising: a plurality of semiconductor packages. At least one of the semiconductor packages comprises: a wiring board having a first surface and a second surface opposite to the first surface; a semiconductor chip mounted on the first surface of the wiring board; and a mounting connection terminal electrically connecting a bonding pad of the semiconductor chip to a first connection pad of the wiring board, the mounting connection terminal including a core portion and a connecting shell solder portion substantially surrounding the core portion. The core portion of the mounting connection terminal is suspended within the connecting shall solder portion.

### BRIEF DESCRIPTION OF THE DRAWINGS

Embodiments will be described in view of the attached drawings and accompanying detailed description.

FIG. 1 is a cross-sectional view illustrating a semiconductor package according to some embodiments;

FIG. 2 is a cross-sectional view illustrating a semiconductor package according to other embodiments;

FIG. 3 is an enlarged view of a portion ‘A’ of FIG. 1 to illustrate some elements of a semiconductor package according to embodiments;

FIGS. 4, 5, 6A, and 6B are cross-sectional views illustrating methods of fabricating a semiconductor package according to embodiments;

FIG. 7 is a cross-sectional view illustrating a semiconductor package according to still other embodiments;

FIG. 8 is a plan view illustrating a package module according to embodiments;

FIG. 9 is a schematic block diagram illustrating a memory card according to embodiments;

FIG. 10 is a schematic block diagram illustrating an electronic system according to embodiments; and

FIG. 11 is a perspective view illustrating an electronic device according to embodiments.

### DETAILED DESCRIPTION OF THE EMBODIMENTS

Embodiments will now be described more fully hereinafter with reference to the accompanying drawings, in which exemplary embodiments are shown. The advantages and features and methods of achieving them will be apparent from the following exemplary embodiments that will be described in more detail with reference to the accompanying drawings. It should be noted, however, that embodiments are not limited to the following exemplary embodiments, and may be implemented in various forms. Accordingly, the exemplary embodiments are provided only for better understanding by those skilled in the art.

In the drawings, embodiments are not limited to the specific examples provided herein and may be exaggerated for clarity.

The terminology used herein is for the purpose of describing particular embodiments only and is not intended to be limiting. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views. Accordingly, shapes of the exemplary views may be modified according to manufacturing techniques and/or allowable errors and/or variations. Therefore, the embodiments are not limited to the specific shape illustrated in the exemplary views, but may include other shapes that may be created according to manufacturing processes. Areas exemplified in the drawings have general properties, and are used to illustrate specific shapes of elements. Thus, this should not be construed as limiting the scope.

It will be also understood that although the terms first, second, third etc. may be used herein to describe various elements, these elements should not be limited by these terms. These terms are only used to distinguish one element from another element. Thus, a first element in some embodiments could be termed a second element in other embodiments.

Exemplary embodiments of aspects explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region, layer, or the like illustrated as a rectangle may have rounded or curved features. Thus, the regions illustrated in the figures are schematic in nature and their shapes are not intended to illustrate the actual shape of a region of a device and are not intended to limit the scope of example embodiments.

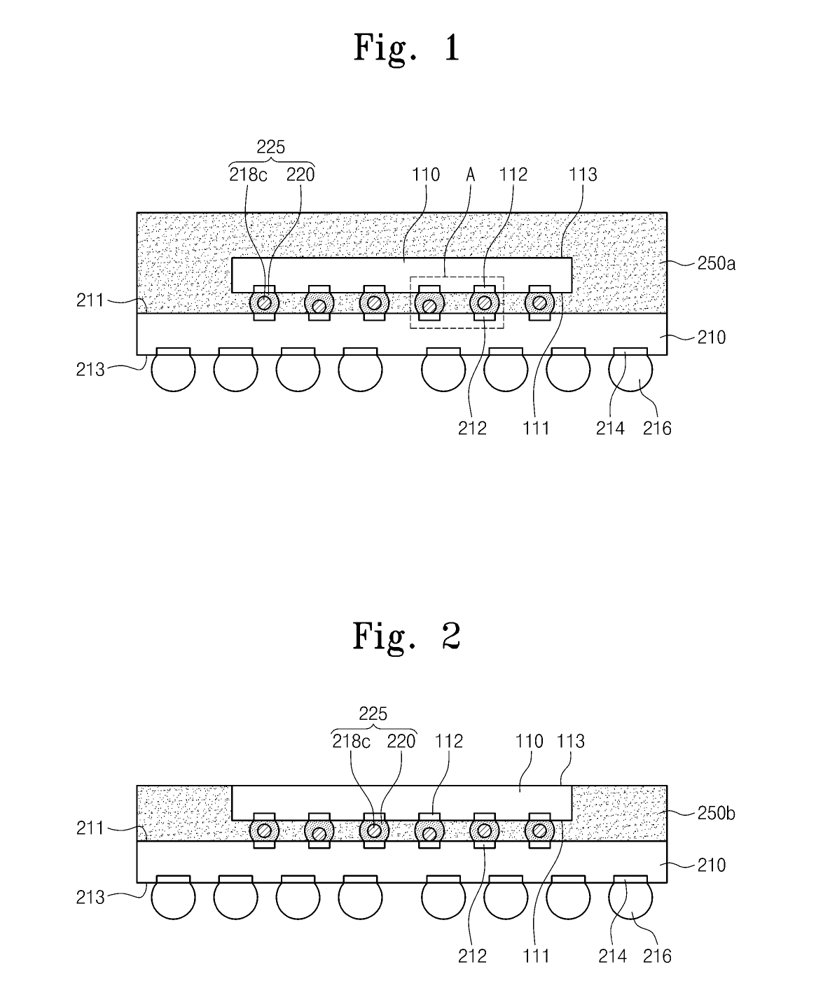

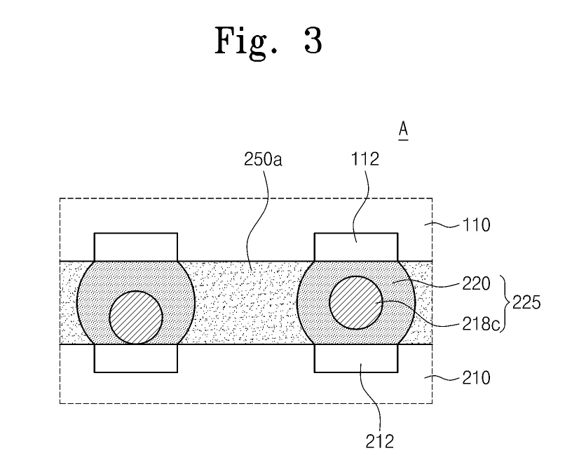

FIG. 1 is a cross-sectional view illustrating a semiconductor package according to some embodiments. FIG. 3 is an enlarged view of a portion ‘A’ of FIG. 1 to illustrate some elements of a semiconductor package according to embodiments.

Referring to FIGS. 1 and 3, a semiconductor package may include a semiconductor chip 110, a wiring board 210, mounting connection terminals 225, and a molding part 250a. The semiconductor chip 110 has an active surface 111 and a back surface 113 opposite to the active surface 111. Bonding pads 112 are disposed on the active surface 111 of the semiconductor chip 110. The bonding pads 112 may have a predetermined bonding pad array on the active surface 111 of the semiconductor chip 110. Even though not shown in the drawings, the semiconductor chip 110 according to embodiments may be a semiconductor chip group. The semiconductor chip group may include a plurality of stacked semiconductor chips electrically connected to each other by through-via electrodes. In this case, the bonding pads 112 may be provided on an active surface of a lowermost semiconductor chip of the semiconductor chip group. The through-via electrodes penetrating the semiconductor chip group may be electrically connected to the bonding pads 112.

The wiring board 210 may have a top surface 211 and a bottom surface 213 opposite to the top surface. The wiring board 210 may include upper connection pads 212 disposed on the top surface 211 and lower connection pads 214 disposed on the bottom surface 213. The upper connection pads 212 and the lower connection pads 214 may be connected to circuit patterns (not shown) disposed within the wiring board 210. The wiring board 210 may be a printed circuit board (PCB), a substrate, or the like. The upper connection pads 212 of the wiring board 210 may be electrically connected to the bonding pads 112 of the semiconductor chip 110. In other words, the semiconductor chip 110 may be mounted on the top surface 211 of the wiring board 210. External connection terminals 216 may be provided on the lower connection pads 214 of the wiring board 210. The semiconductor package may be electrically connected to an external system through the external connection terminals 216. The external connection terminals 216 may be conductive bumps, solder balls, conductive spacers, a pin grid array (PGA), combinations of such structures, or the like. In an embodiment, the external connection terminals 216 may be solder balls.

The bonding pads 112 of the semiconductor chip 110 may be electrically connected to the upper connection pads 212 of the wiring board 210 through the mounting connection terminals 225. In other words, the semiconductor chip 110 may be mounted on the top surface of the wiring board 210 by a flip chip bonding technique. Each of the mounting connection terminals 225 may be shaped like a solder ball.

Each of the mounting connection terminals 225 may include a core portion 218c and a connecting shell solder portion 220 surrounding the core portion 218c. The core portion 218c of the mounting connection terminal 225 may have a globular shape or a structure shaped like a sphere. The core portion 218c of the mounting connection terminal 225 may or may not be in contact with the bonding pads 112 of the semiconductor chip 110.

Additionally, the core portion 218c of the mounting connection terminal 225 may or may not be in contact with the upper connection pads 212 of the wiring board 210. In other words, the core portion 218c may be substantially if not completely surrounded by the connecting shell solder portion 220, so as to be disposed within the connecting shell solder portion 220, may contact the bonding pad 112, or may contact the upper connection pads 212. The core portion 218c may include a metal or a polymer. The metal may include copper (Cu) or other conductive metals and/or alloys. The polymer may be non-conductive. The connecting shell solder portion 220 may be formed of a solder material including tin (Sn), indium (In), combinations of such materials, or the like.

If the core portion 218c includes the metal, the mounting connection terminal 225 may improve an electrical connecting characteristic between the semiconductor chip 110 and the wiring board 210. Additionally, the core portion 218c including the metal may maintain a physical shape of the mounting connection terminal 225 between the semiconductor chip 110 and the wiring board 210. Likewise, if the core portion 218c includes the non-conductive polymer, a physical shape of the mounting connection terminal 225 may be maintained between the semiconductor chip 110 and the wiring board 210. Thus, reliability of the semiconductor package can be improved.

The molding part 250a may cover a top surface of the wiring board 210 and the semiconductor chip 110. Additionally, the molding part 250a may fill a space between the semiconductor chip 110 and the wiring board 210. For example, the molding part 250a may be a molded underfill (MUF) covering the back surface 113 of the semiconductor chip 110 mounted on the wiring board 210. The molding part 250a may include an epoxy molding compound (EMC). The molding part 250a may have a sidewall substantially coplanar with a sidewall of the wiring board 210, as illustrated in FIG. 1. However, embodiments are not limited thereto. In another embodiment, the molding part 250a may have a sidewall inclined with respect to the top surface of the wiring board 210.

Hereinafter, a semiconductor package according to other embodiments will be described with reference to FIG. 2. FIG. 2 is a cross-sectional view illustrating a semiconductor package according to other embodiments. In the present embodiment, the same elements as described in the aforementioned embodiments will be indicated by the same reference numerals or the same reference designators. The descriptions to the same elements as in the aforementioned embodiments will be omitted or mentioned briefly for the purpose of ease and convenience in explanation.

A semiconductor package according to the present embodiment in FIG. 2 may include a molding part 250b exposing the back surface 113 of the semiconductor chip 110 mounted on the wiring board 210, unlike the semiconductor package illustrated in FIG. 1.

The molding part 250b may cover the top surface 211 of the wiring board 210 and the sidewalls of the semiconductor chip 110 and may fill the space between the semiconductor chip 110 and the wiring board 210. The molding part 250b may be an exposed-MUF (e-MUF) exposing the back surface 113 of the semiconductor chip 110 mounted on the wiring board 210. The molding part 250b may include an epoxy molding compound. The molding part 250b may have a sidewall coplanar with the sidewall of the wiring board 210 as illustrated in FIG. 3. However, embodiments are not limited thereto. In another embodiment, the molding part 250b may have a sidewall inclined with respect to the top surface of the wiring board 210. As a result, the semiconductor package may include the semiconductor chip 110 of which the back surface 113 is exposed. Thus, a height of the semiconductor package may be reduced.

According to embodiments, the semiconductor chip 110 may be mounted on the wiring board 210 through the mounting connection terminals 225 by the flip chip bonding technique, and each of the mounting connection terminals 225 may include the core portion 218c and the connecting shell solder portion 220 surrounding the core portion 218c. Thus, a distance between the mounting connection terminals 225 may be reduced, and the shapes of the mounting connection terminals 225 may be maintained. As a result, the semiconductor chip having a solder ball layout with a fine pitch may be more reliably mounted on the wiring substrate 210 by the flip chip bonding technique. Thus, physical and/or electrical reliability of the semiconductor package may be improved.

Additionally, the semiconductor package according to an embodiment includes the mounting connection terminal 225 having the core portion 218c and the connecting shell solder portion 220 surrounding the core portion 218c, unlike a conventional mounting connection terminal formed of only a solder material. If a solder ball layout consists of the conventional mounting connection terminals, a pitch of the solder ball layout may be greater than about 125 μm. However, according to embodiments, a height of the mounting connection terminal 225 may be sufficiently secured to realize the solder ball layout having the fine pitch of about 125 μM or less.

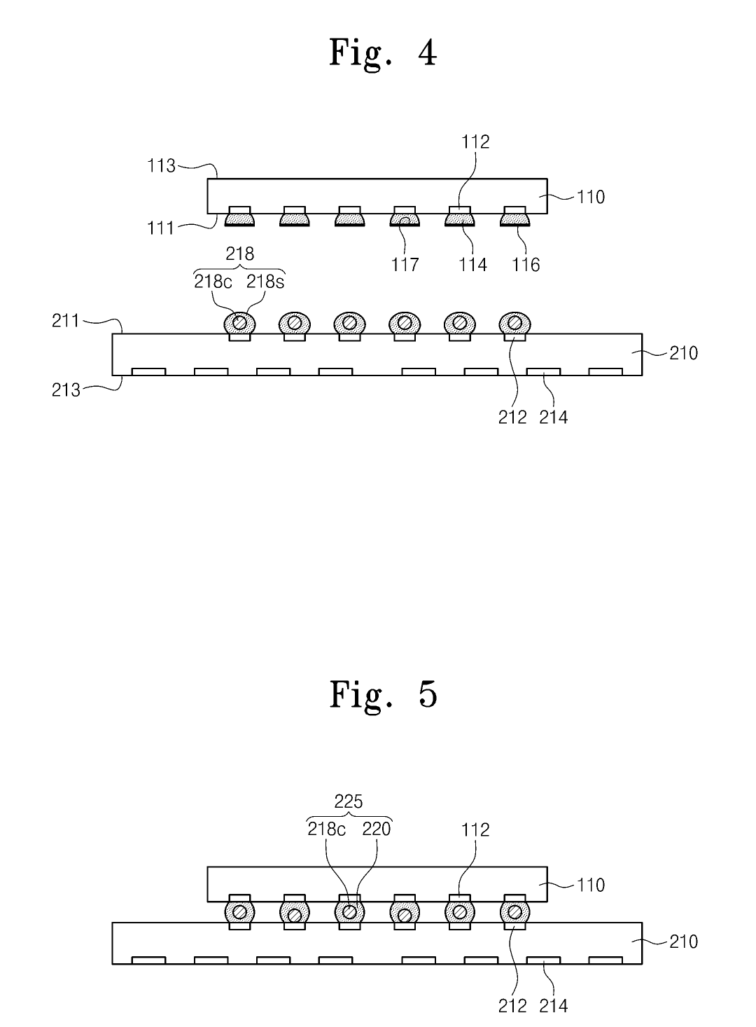

FIGS. 4, 5, 6A, and 6B are cross-sectional views illustrating methods of fabricating a semiconductor package according to embodiments. Referring to FIG. 4, a wiring board 210 is prepared. The wiring board 210 includes a top surface 211, a bottom surface 213 opposite to the top surface 211, and upper connection pads 212 disposed on the top surface 211.

The wiring board 210 may further include lower connection pads 214 disposed on the bottom surface 213 thereof. The upper and lower connection pads 212 and 214 may be connected to circuit patterns (not shown) disposed within the wiring board 210. The wiring board 210 may be a printed circuit board (PCB), a substrate, or the like.

A wiring board-connection terminal 218 may be formed on each of the upper connection pads 212 of the wiring board 210. The wiring board-connection terminal 218 includes a core portion 218c and a mounting shell solder portion 218s surrounding the core portion 218c.

The core portion 218c of the wiring board-connection terminal 218 may have a globular shape. In other words, the core portion 218c may be substantially if not completely surrounded by the mounting shell solder portion 218s, such that the core portion 218c may be suspended within the mounting shell solder portion 218s. Alternatively, the core portion 218c may be in contact with the upper connection pad 212 of the wiring board 210. In an embodiment, the core portions 218c may be substantially if not completely surrounded by a connecting shell solder portion 220 of FIG. 5 in a reflow process for formation of a mounting connection terminal 225 of FIG. 5. The core portion 218c may include a metal or a polymer. The metal may include copper (Cu) or other conductive metals and/or alloys. The polymer may be non-conductive. The mounting shell solder portion 218s may be formed of a solder material including tin, indium, combinations of such materials, or the like.

A semiconductor chip 110 is prepared. The semiconductor chip 110 includes an active surface 111, a back surface 113 opposite to the active surface 111, and bonding pads 112 disposed on the active surface 111.

The bonding pads 112 of the semiconductor chip 110 may have a predetermined bonding pad array disposed on the active surface 111. Even though not shown in the drawings, the semiconductor chip 110 according to embodiments may be a semiconductor chip group. The semiconductor chip group may include a plurality of stacked semiconductor chips electrically connected to each other by through-via electrodes. In this case, the bonding pads 112 may be provided on an active surface 111 of a lowermost semiconductor chip of the semiconductor chip group. The through-via electrodes penetrating the semiconductor chip group may be electrically connected to the bonding pads 112.

A semiconductor chip-connection terminal 114 may be formed on each of the bonding pads 112 of the semiconductor chip 110. The semiconductor chip-connection terminal 114 may have a top surface 117 spaced apart from the bonding pad 112, and the top surface 117 of the semiconductor chip-connection terminal 114 may be substantially flat. The semiconductor chip-connection terminal 114 of which the top surface 117 is substantially flat may have a coined shape. In an embodiment, a preliminary terminal of a solder ball shape may be formed on the bonding pad 112 of the semiconductor chip 110 and then the preliminary terminal may be pressed to form the semiconductor chip-connection terminal 114 having the substantially flat top surface 117 spaced apart from the bonding pad 112. Alternatively, a preliminary terminal of a solder ball shape may be formed on the bonding pad 112 of the semiconductor chip 110 and then the preliminary terminal may be cut to form the semiconductor chip-connection terminal 114 having the substantially flat top surface 117 spaced apart from the bonding pad 112. Thus, the amount of the solder material for formation of a mounting connection terminal 225 of FIG. 5 may be reduced to reduce fabrication costs of the semiconductor package. The semiconductor chip-connection terminal 114 may be formed of a solder material including tin and indium.

A flux 116 may be coated on the substantially flat top surface of the semiconductor chip-connection terminal 114. The flux 116 may clean a bonding portion between the mounting shell solder portion 218s of the wiring board-connection terminal 218 and the semiconductor chip-connection terminal 114 in a process of forming one mounting connection terminal from the wiring board-connection terminal 218 and the semiconductor chip-connection terminal 114. Additionally, the flux 116 may prevent an oxide from occurring in the process of the one mounting connection terminal, such that the bonding of the wiring board-connection terminal 218 and the semiconductor chip-connection terminal 114 may be reliably formed.

Referring to FIG. 5, the semiconductor chip 110 is mounted on the top surface of the wiring board 210 by a flip chip bonding technique in order that the semiconductor chip-connection terminal 114 becomes in contact with the wiring board-connection terminal 218.

A reflow process may be performed, so that the wiring board-connection terminal 218 and the semiconductor chip-connection terminal 114 may be formed into one mounting connection terminal 225. The mounting connection terminal 225 may include the core portion 218c and a connecting shell solder portion 220 surrounding the core portion 218c. The core portion 218c of the mounting connection terminal 225 may not be in contact with the bonding pads 112 of the semiconductor chip 110. This is because a volume of the semiconductor chip-connection terminal 114 is greater than a volume of the mounting shell solder portion 218s of the wiring board-connection terminal 218. Additionally, the core portion 218c of the mounting connecting terminal 225 may not be in contact with the upper connection pad 212 of the wiring board 210. In other words, the core portion 218c may be substantially if not completely surrounded by the connecting shell solder portion 220, such that it may be suspended within the connecting shell solder portion 220. The connecting shell solder portion 220 may be formed by bonding of the mounting shell solder portion 218s of the wiring board-connection terminal 218 and the semiconductor chip-connection terminal 114. Thus, the connecting shell solder portion 220 may include the solder material including tin indium, combinations of such materials, or the like.

If the core portion 218c includes the metal, the mounting connection terminal 225 may improve an electrical connecting characteristic between the semiconductor chip 110 and the wiring board 210, and a physical shape of the mounting connection terminal 225 may be maintained between the semiconductor chip 110 and the wiring board 210. Likewise, if the core portion 218c includes the non-conductive polymer, the physical shape of the mounting connection terminal 225 may be maintained between the semiconductor chip 110 and the wiring board 210. Thus, reliability of the semiconductor package may be improved.

The bonding pads 112 of the semiconductor chip 110 may be electrically connected to the upper connection pads 212 of the wiring board 210 through the mounting connection terminals 225. In other words, the semiconductor chip 110 may be mounted on the top surface 211 of the wiring board 210 using the flip chip bonding technique. Each of the mounting connection terminals 225 may be a solder ball including the core portion 218c and the connecting shell solder portion 220 surrounding the core portion 218c.

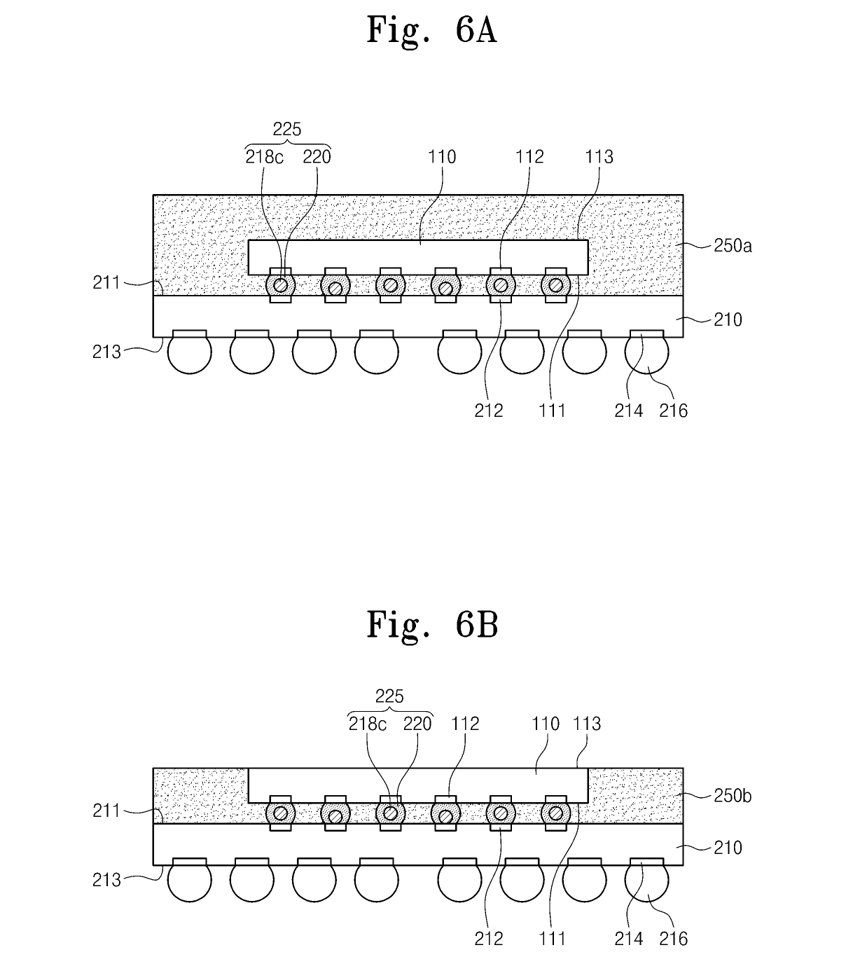

In some embodiments, referring to FIG. 6A, a molding part 250a may be formed to cover the top surface 211 of the wiring board 210 and the semiconductor chip 110 and to fill a space between the semiconductor chip 110 and the wiring board 210. In other words, the molding part 250a may be a molded underfill (MUF) covering the back surface 113 of the semiconductor chip 110 mounted on the wiring board 210. The molding part 250a may include an epoxy molding compound (EMC). The molding part 250a may have a sidewall coplanar with a sidewall of the wiring board 210, as illustrated in FIG. 6A. However, embodiments are not limited thereto. In another embodiment, the molding part 250a may have a sidewall inclined with respect to the top surface 211 of the wiring board 210.

In other embodiments, referring to FIG. 6B, a molding part 250b may be formed to cover the top surface 211 of the wiring board 210 and the sidewalls of the semiconductor chip 110 and to fill the space between the semiconductor chip 110 and the wiring board 210. The molding part 250b may be an exposed-MUF (e-MUF) exposing the back surface 113 of the semiconductor chip 110 mounted on the wiring board 210. The molding part 250b may include an epoxy molding compound. The molding part 250b may have a sidewall coplanar with the sidewall of the wiring board 210 as illustrated in FIG. 6B. However, embodiments are not limited thereto. In another embodiment, the molding part 250b may have a sidewall inclined with respect to the top surface 211 of the wiring board 210. As a result, the semiconductor package may include the semiconductor chip 110 of which the back surface 113 is exposed. Thus, a height of the semiconductor package may be reduced.

External connection terminals 216 may be formed on the lower connection pads 214 of the wiring board 210, respectively. The semiconductor package may be electrically connected to an external system through the external connection terminals 216. The external connection terminals 216 may be conductive bumps, solder balls, conductive spacers, a pin grid array (PGA), combinations of such structures, or the like. In an embodiment, the external connection terminals 216 may be solder balls.

Alternatively, the external connection terminals 216 may be formed on the lower connection pads 214 of the wiring board 210 before the molding part 250a or 250b is formed.

In the method of fabricating the semiconductor package according to embodiments, the semiconductor chip 110 may be mounted on the wiring board 210 through the mounting connection terminals 225 by the flip chip bonding technique, and each of the mounting connection terminals 225 may include the core portion 218c and the connecting shell solder portion 220 surrounding the core portion 218c. Thus, a distance between the mounting connection terminals 225 may be reduced, and the shapes of the mounting connection terminals 225 may be maintained. As a result, the semiconductor chip having a solder ball layout of a fine pitch may be more reliably mounted on the wiring substrate 210 by the flip chip bonding technique. Thus, physical and/or electrical reliability of the semiconductor package may be improved.

Additionally, the semiconductor package according to an embodiment includes the mounting connection terminal having the core portion 218c and the connecting shell solder portion 220 surrounding the core portion 218c, unlike a conventional mounting connection terminal formed of only a solder material. If a solder ball layout consists of the conventional mounting connection terminals, a pitch of the solder ball layout may be greater than about 125 μm. However, according to embodiments, a height of the mounting connection terminal 225 may be sufficiently secured, such that the semiconductor chip including the solder ball layout having the fine pitch of about 125 μM or less may be reliably mounted on the wiring board 210 by the flip chip bonding technique.

Although techniques of forming the semiconductor package have been described above with the core portions 218c being disposed in the mounting shell solder portions 218s, the core portions 218c may be disposed in other locations before mounting the semiconductor chip 110 on the wiring board 210. For example, the core portions 218c may be disposed in the semiconductor chip-connection terminals 114, distributed among the semiconductor chip-connection terminals 114 and the mounting shell solder portions 218s, or the like. Moreover, although the wiring board-connection terminal 218 and semiconductor chip-connection terminals 114 have been described as being disposed on the upper connection pads 212 and bonding pads 112, respectively, the wiring board-connection terminal 218 and semiconductor chip-connection terminals 114 may be disposed on different locations. For example, the wiring board-connection terminal 218 may be disposed on the bonding pads 112 and the semiconductor chip-connection terminals 114 may be disposed on the upper connection pads 212. Regardless, when the semiconductor chip 110 is mounted on the wiring board 210, the core portion 218c may be disposed in the connecting shell solder portion 220.

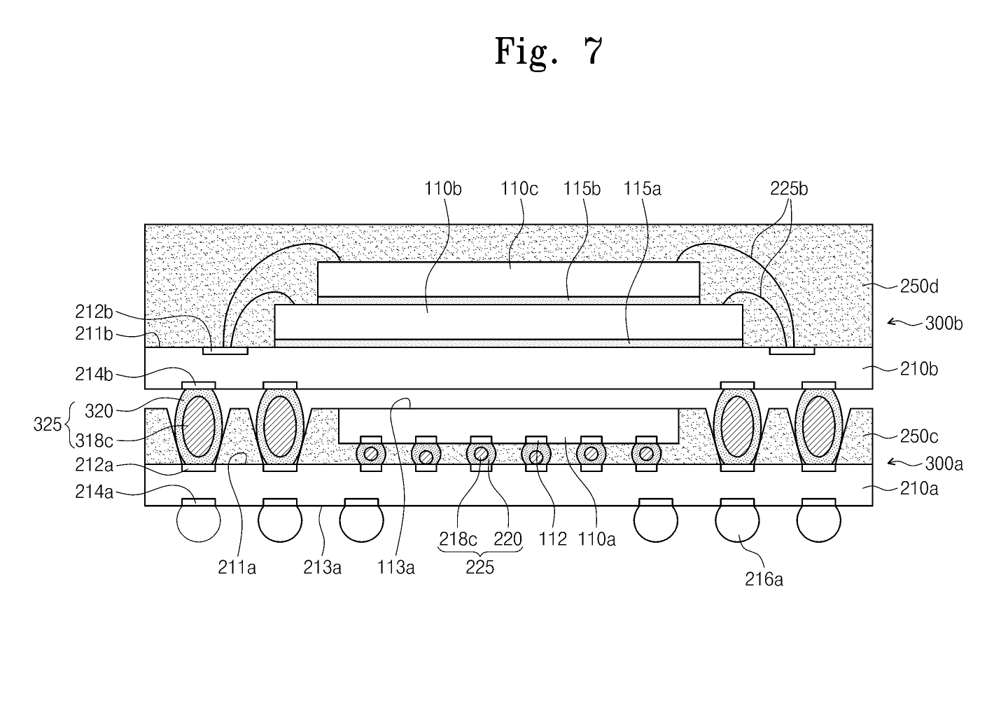

FIG. 7 is a cross-sectional view illustrating a semiconductor package according to still other embodiments. Referring to FIG. 7, a semiconductor package may include a lower package 300a, an upper package 300b, and at least one stack-connection terminal 325. The lower package 300a includes a lower wiring board 210a and at least one lower semiconductor chip 110a mounted on the lower wiring board 210a. The upper package 300b includes an upper wiring board 210b and at least one upper semiconductor chip 110b and/or 110c mounted on the upper wiring board 210b. The stack-connection terminal 325 may be connected to signal wires (not shown) respectively disposed within the lower and upper wiring boards 210a and 210b.

The stack-connection terminal 325 may include a core portion 318c and a stack-shell solder portion 320 surrounding the core portion 318c. The core portion 318c of the stack-connection terminal 325 may have a globular shape. The core portion 318c of the stack-connection terminal 325 may or may not be in contact with upper connection pads 212a of the lower wiring board 210a and/or lower connection pads 214b of the upper wiring board 210b. In other words, the core portion 318c may be substantially if not completely surrounded by the stack-shell solder portion 320, such that it may be disposed within the stack-shell solder portion 320. The core portion 318c may include a metal or a polymer. The metal of the core portion 318c may include copper or other conductive metals and/or alloys.

The polymer of the core portion 318c may be non-conductive. The stack-shell solder portion 320 may be formed of a solder material including tin, indium, combinations of such materials, or the like.

If the core portion 318c includes the metal, the stack-connection terminal 325 may improve an electrical connecting characteristic between the lower and upper wiring boards 210a and 210b, and a physical shape of the stack-connection terminal 325 may be maintained between the lower and upper wiring boards 210a and 210b. Likewise, if the core portion 318c includes the non-conductive polymer, the physical shape of the stack-connection terminal 325 may be maintained between the lower and upper wiring boards 210a and 210b. Thus, reliability of the semiconductor package may be improved.

The semiconductor package according to the present embodiment may have a package-on-package (PoP) shape including the lower package 300a and the upper package 300b stacked on the lower package 300a. The lower and upper packages 300a and 300b may have substantially the same planar area. Alternatively, the lower and upper packages 300a and 300b may have planar areas different from each other, respectively. The semiconductor package according to the present embodiment may further include a lower molding part 250c and an upper molding part 250d. The lower molding part 250c may cover a top surface 211a of the lower wiring board 210a on which the lower semiconductor chip 110a is mounted. The upper molding part 250d may cover a top surface 211b of the upper wiring board 210b on which the upper semiconductor chip 110b and/or 110c is mounted. The lower and upper molding parts 250c and 250d may include an epoxy molding compound. The lower molding part 250c may include openings exposing the upper connection pads 212a of the lower wiring board 210a. Thus, the upper package 300b may be electrically connected to the lower package 300a through the stack-connection terminals 325 and may be stacked on the lower package 300a.

The lower semiconductor chip 110a and the upper semiconductor chip 110b and/or 110c may be mounted on the lower wiring board 210a and the upper wiring board 210b by a flip chip bonding technique and/or a wiring bonding technique, respectively. Thus, the lower semiconductor chip 110a and the upper semiconductor chip 110b and/or 110c may be electrically connected on the lower wiring board 210a and the upper wiring board 210b, respectively. As illustrated in FIG. 7, the lower semiconductor chip 110a may be mounted on the lower wiring board 210a through mounting connection terminals 225 by the flip chip bonding technique, so as to be electrically connected to the lower wiring board 210a. The upper semiconductor chips 110b and 110c may be mounted on the upper wiring board 210b using semiconductor chip-adhesive layers 115a and 115b and connection-bonding wires 225b by the wire bonding technique, so as to be electrically connected to the upper wiring board 210b. However, embodiments are not limited thereto as the upper semiconductor chips 110b and 110c may be mounted on and electrically coupled to the upper wiring board 210b using other techniques. The lower semiconductor chip 110a and the upper semiconductor chip 110b and/or 110c may be a volatile memory device (e.g., a dynamic random access memory (DRAM) device, and/or a static random access memory (SRAM) device), a non-volatile memory device (e.g., a flash memory device), a photo-electronic device, a logic device, a communication device, a digital signal processor (DSP), a system-on-chip (SoC), or the like.

The semiconductor package may further include at least one external connection terminal 216a disposed on a bottom surface 213a of the lower wiring board 210a. The semiconductor package may be electrically connected to a mother board or other devices through the external connection terminal 216a.

Although a back surface 113a of the lower semiconductor chip 110a is illustrated as being exposed by the lower molding part 250c, in other embodiments, the back surface 113a of the lower semiconductor chip 110a may be covered by the lower molding part 250c similar to the molding part 250a described with respect to FIG. 1. Furthermore, although only one lower semiconductor chip 110a has been illustrated, multiple semiconductor chips may be mounted on the lower wiring board 210a as described above.

In addition, although the lower semiconductor chip 110a and upper semiconductor chip 110b and/or 110c are illustrated as being mounted on the respective lower wiring board 210a and upper wiring board 210b using different techniques, the lower semiconductor chip 110a and upper semiconductor chip 110b and/or 110c may be mounted using similar techniques. For example, the upper semiconductor chip 110b may be mounted on the upper wiring board 210b using mounting connection terminals 225.

Although only two wiring boards, the lower wiring board 210a and the upper wiring board 210b, have been described as being stacked, any number of wiring boards with associated semiconductor chips may be stacked.

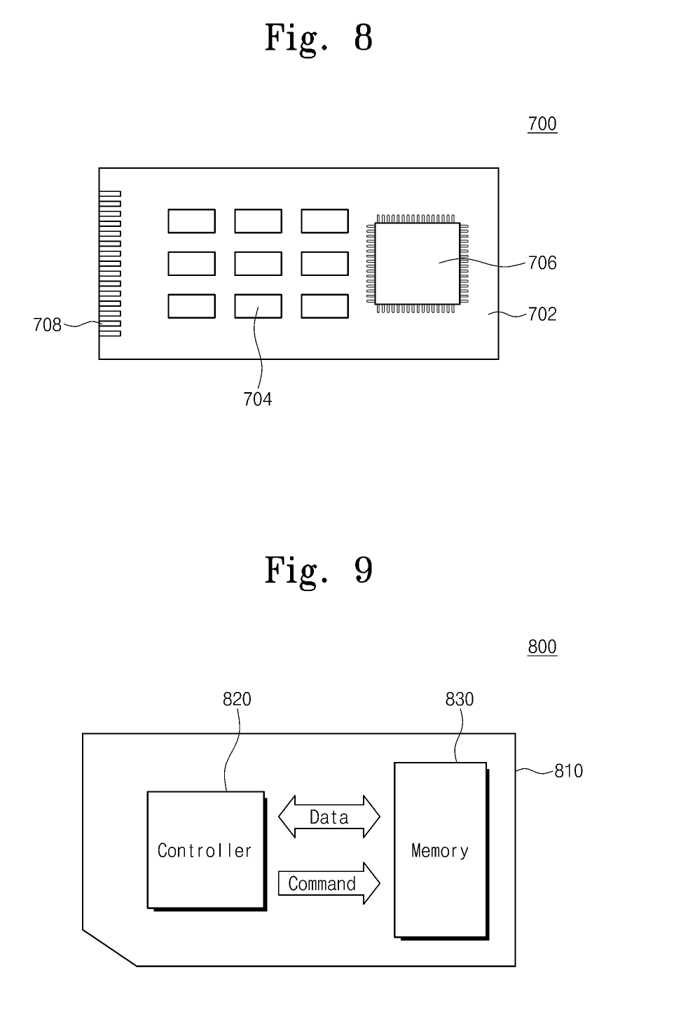

FIG. 8 is a plan view illustrating a package module according to embodiments. Referring to FIG. 8, a package module 700 may include a module board 702 having external connection terminals 708, one or more semiconductor chips 704, and a semiconductor package 706 of a quad flat package (QFP) type. The semiconductor chip 704 and the semiconductor package 706 may be mounted on the module board 702. The semiconductor package 704 may include one of the semiconductor packages according to embodiments. The package module 700 may be connected to an external electronic device through the external connection 708.

In another embodiment, a packaging technique described above may be used with a suitable wiring board or other substrate to form a QFP-type package or other package types. Accordingly, a packaging technique described above may be used in the semiconductor package 706.

FIG. 9 is a schematic block diagram illustrating a memory card according to embodiments. Referring to FIG. 9, a memory card 800 may include a controller 820 and a memory device 830 installed in a housing 810. The controller 820 may exchange electrical signals with the memory device 830. For example, the controller 820 and the memory device 830 may exchange data with each other according to commands of the controller 820. Thus, the memory card 800 may store data in the memory device 830 or may output data from the memory device 830 to an external system.

The controller 820 and/or the memory device 830 may include at least one of the semiconductor packages according to the aforementioned embodiments. For example, the controller 820 may include a system in package, and the memory device 830 may include a multi-chip package. Alternatively, the controller 820 and/or the memory device 830 may be formed into a stack type package. The memory card 800 may be used as a data storage medium of various portable devices. For example, the memory card 800 may be realized as a multimedia card (MMC), a secure digital (SD) card, or the like.

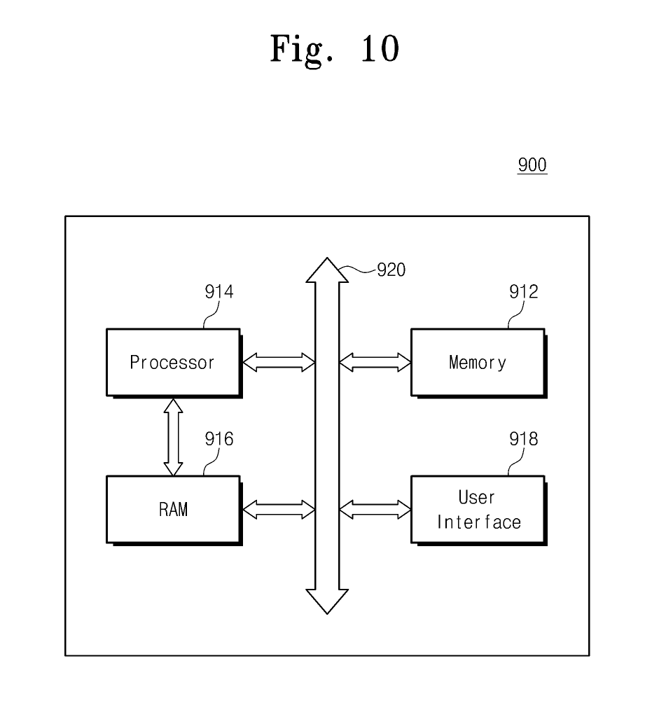

FIG. 10 is a schematic block diagram illustrating an electronic system according to embodiments. Referring to FIG. 10, an electronic system 900 may include at least one of the semiconductor packages according to the aforementioned embodiments. The electronic system 900 may include a mobile device or a computer. For example, the electronic system 900 may include a memory system 912, a processer 914, a random access memory (RAM) device 916, and a user interface unit 918. At least two of the memory system 912, the processor 914, the RAM device 916, and the user interface unit 918 may communicate with each other through the data bus 920. The processor 914 may execute a program and may control the electronic system 900. The RAM device 916 may be used as an operation memory device of the processor 914. Each of the processor 914 and the RAM device 916 may include at least one of the semiconductor packages according to the aforementioned embodiments. Alternatively, the processor 914 and the RAM device 916 may be included in one package. The user interface unit 918 may be used for data input/data output of the electronic system 900. The memory system 912 may store code for operation of the processor 914, data processed by the processor 914, and/or data inputted from an external system. The memory system 912 may include a controller and a memory device. The memory system 912 may include substantially the same structure as the memory card 800 of FIG. 9.

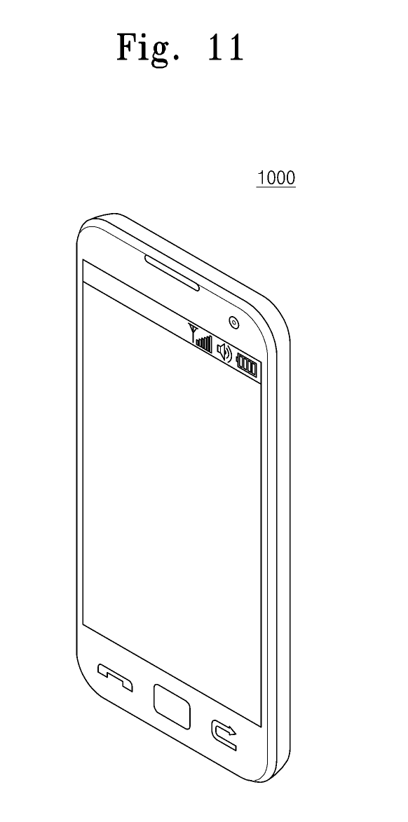

The electronic system 900 may be applied to electronic control devices of various electronic devices. FIG. 11 illustrates a mobile phone 1000 including the electronic system 900 of FIG. 10. In other embodiments, the electronic system 900 of FIG. 10 may be applied to portable notebooks, MP3 players, navigations, solid state disks (SSDs), consumer electronics, vehicles, household appliances, or the like.

According to embodiments, the semiconductor chip may be mounted on the wiring board through the mounting connection terminal by the flip chip bonding technique, and the mounting connection terminal may include the core portion and the connecting shell solder portion surrounding the core portion. Thus, the distance between the mounting connection terminals may be reduced, and the shapes of the mounting connection terminals may be maintained. As a result, the semiconductor chip having the solder ball layout of a fine pitch may be reliably mounted on the wiring substrate by the flip chip bonding technique. Thus, physical and/or electrical reliability of the semiconductor package may be improved.

Embodiments are directed to semiconductor packages and methods of fabricating the same.

In an embodiment, a semiconductor package may include: a wiring board having a first surface and a second surface opposite to the first surface; a semiconductor chip mounted on the first surface of the wiring boarding by a flip chip bonding technique; and a mounting connection terminal electrically connecting a bonding pad of the semiconductor chip to a first connection pad of the wiring board, the mounting connection terminal including a core portion and a connecting shell solder portion surrounding the core portion. The core portion of the mounting connection terminal may not be in contact with the bonding pad of the semiconductor chip.

In an embodiment, the core portion of the mounting connection terminal may not be in contact with the first connection pad of the wiring board.

In an embodiment, the core portion may include a metal or a polymer.

In an embodiment, the semiconductor package may further include: a molding part covering the first surface of the wiring board and sidewalls of the semiconductor chip and filling a space between the semiconductor chip and the wiring board. In an embodiment, the molding part may further cover a back surface of the semiconductor chip.

In an embodiment, the wiring board may further include a second connection pad provided on the second surface. In an embodiment, the semiconductor package may further include: an external connection terminal provided on the second connection pad of the wiring board.

In another aspect, a method of fabricating a semiconductor package may include: preparing a wiring board including a first surface, a second surface opposite to the first surface, and a first connection pad disposed on the first surface; forming a wiring board-connection terminal on the first connection pad of the wiring board, the wiring board-connection terminal including a core portion and a connecting shell solder portion surrounding the core portion; preparing a semiconductor chip including an active surface, a back surface opposite to the active surface, and a bonding pad disposed on the active surface; forming a semiconductor chip-connection terminal on the bonding pad of the semiconductor chip; mounting the semiconductor chip on the wiring board by a flip chip bonding technique in order that the semiconductor chip-connection terminal becomes in contact with the wiring board-connection terminal; performing a reflow process on the wiring board-connection terminal and the semiconductor chip-connection terminal to form a mounting connection terminal The mounting connection terminal may include the core portion and a mounting shell solder portion surrounding the core portion; and the core portion of the mounting connection terminal may not be in contact with the bonding pad of the semiconductor chip.

In an embodiment, the core portion of the mounting connection terminal may not be in contact with the first connection pad of the wiring board.

In an embodiment, the core portion may include a metal or a polymer.

In an embodiment, the method may further include: coating a flux on a top surface of the semiconductor chip-connection terminal.

In an embodiment, the method may further include: forming a molding part which covers the first surface of the wiring board and sidewalls of the semiconductor chip and fills a space between the semiconductor chip and the wiring board. In an embodiment, the molding part may be formed to further cover the back surface of the semiconductor chip.

In an embodiment, the wiring board may further include a second connection pad disposed on the second surface. In this case, the method may further include: forming an external connection terminal on the second connection pad.

While embodiments have been described with reference to example embodiments, it will be apparent to those skilled in the art that various changes and modifications may be made without departing from the spirit and scope. Therefore, it should be understood that the above embodiments are not limiting, but illustrative. Thus, the scope is to be determined by the broadest permissible interpretation of the following claims and their equivalents, and shall not be restricted or limited by the foregoing description.

What is claimed is:

1. A method of fabricating a semiconductor package, the method comprising:
preparing a wiring board including a first connection pad;
forming a wiring board-connection terminal on the first connection pad of the wiring board, the wiring board-connection terminal including a core portion and a connecting shell solder portion substantially surrounding the core portion;
providing a semiconductor chip including a bonding pad;
forming a semiconductor chip-connection terminal on the bonding pad of the semiconductor chip;
contacting the semiconductor chip-connection terminal to the wiring board-connection terminal; and
performing a reflow process on the wiring board-connection terminal and the semiconductor chip-connection terminal to form a mounting connection terminal, wherein:
the mounting connection terminal includes the core portion and a mounting shell solder portion substantially surrounding the core portion; and
the core portion of the mounting connection terminal is not in contact with the bonding pad of the semiconductor chip.

2. The method of claim 1, wherein the core portion of the mounting connection terminal is not in contact with the first connection pad of the wiring board.

3. The method of claim 1, wherein the core portion includes a metal or a polymer.

4. The method of claim 1, wherein:
the semiconductor chip-connection terminal has a top surface spaced apart from the bonding pad; and
the top surface of the semiconductor chip-connection terminal is substantially flat.

5. The method of claim 4, further comprising:
coating a flux on the top surface of the semiconductor chip-connection terminal.

6. The method of claim 1, further comprising:
forming a molding part which covers the first surface of the wiring board and sidewalls of the semiconductor chip and fills a space between the semiconductor chip and the wiring board.

7. The method of claim 6, wherein the molding part is formed to further cover the back surface of the semiconductor chip.

8. The method of claim 1, wherein the wiring board further includes a second connection pad disposed on the second surface,
the method, further comprising:
forming an external connection terminal on the second connection pad.
